(19) United States
(12) Patent Application Publication
(10) Pub. No.: US 2026/0348814 A1
(43) Pub. Date: Nov. 5, 2026

(54) PARTICLE MONITORING FOR A SEMICONDUCTOR PROCESS CHAMBER

(71) Applicant: Applied Materials, Inc., Santa Clara, CA (US)

(72) Inventors: Viswanath Bavigadda, Bengaluru (IN); Sanat Ghosh, BENGALURU (IN); Mahesh Kumar Singh, BENGALURU (IN); Todd Jonathan Egan, Fremont, CA (US); Mehdi Vaez-Iravani, Los Gatos, CA (US); Moorisetty Kishore KUMAR, Bengaluru (IN); Anand Joy, Bangalore (IN); Hanish Kumar Panavalappil Kumarankutty, Bangalore (IN); Chang Ke, Sunnyvale, CA (US); Changgong Wang, San Jose, CA (US)

(73) Assignee: Applied Materials, Inc., Santa Clara, CA (US)

(21) Appl. No.: 19/194,441

(22) Filed: Apr. 30, 2025

(51) Int. Cl. G01N 15/0205; G01N 15/00; G01N 15/0227; H10P 72/00

(52) U.S. Cl. CPC G01N 15/0211; G01N 15/0227; H10P 72/0402; H10P 72/0604; G01N 2015/0046

(57) ABSTRACT

Disclosed herein is a device and method for monitoring particulate matter present in gases in exhaust streams from semiconductor process chambers and in the chambers. A particle detection system includes a detector housing mounted on an exhaust line of a process device or on a processing chamber. The system includes a laser beam that is directed into a flow stream of particles in the exhaust line or in the chamber and an imaging detector that is mounted with a perpendicular view of the laser beam. The detector identifies particles that scatter the laser light. A method to monitor particulates includes mounting a detector housing, directing a laser beam into a flow stream of particles, mounting an imaging detector with a perpendicular view of the laser beam, and detecting particles in the flow stream as the particles pass through the laser beam.

This disclosure relates to methods and apparatuses for monitoring particulate matter present in gases in exhaust streams from semiconductor process chambers and in the chambers.

### BACKGROUND

In semiconductor device manufacturing, a critical need exists for real time control of the cleanliness of chambers using a non-contact particle measurement technique. Many potential defects may be caused by dirty equipment and/or process conditions that can cause degradation in the yield of the final integrated circuit devices due to nanosized particles being deposited on the device's surface. Numerous processes can be performed on a semiconductor substrate, or wafer, in process chambers. These process may include deposition processes, implantation processes, lithography steps, and more. As each additional wafer is processed in a given process chamber, particles can begin to accumulate inside of the chamber. Particle accumulation inside of the process chamber eventually leads to particles landing on the surface of the wafer being processed. If enough particles are deposited on the surface of a substrate, the particles can damage the electronic components or circuitry on the substrate. In many cases, these damaged wafers must be scrapped due to particulate contamination.

Existing metrology methods for measuring particle contamination have several disadvantages. For example, conventional techniques have high costs, an inability to measure fast-moving particles, a narrow field of view, and a short shelf life.

There remains a need in the art for processes and systems that can detect and measure particulates in process chambers and in exhaust lines from chambers to prevent waste caused by particle accumulation inside the chambers.

### BRIEF SUMMARY

This summary lists several embodiments of the presently disclosed subject matter, and in many cases lists variations and permutations of these embodiments. This summary is merely exemplary of the numerous and varied embodiments. The mention of one or more representative features of a given embodiment is likewise exemplary. Such an embodiment can typically exist with or without the feature(s) mentioned; likewise, those features can be applied to other embodiments of the presently disclosed subject matter, whether listed in this summary or not. To avoid excessive repetition, this Summary does not list or suggest all possible combinations of such features.

In an example, the technology provides a particle detection system that includes a detector housing mounted on an exhaust line of a process device. The system includes a laser beam that is directed into a flow stream of particles in the exhaust line and an imaging detector that is mounted with a perpendicular view of the laser beam. In one aspect of the technology, the laser beam is configured as a laser sheet that covers at least a portion of a cross-sectional area of the exhaust line. In one aspect, the laser sheet is formed by beam shaping optics. In one aspect, the process device is a wafer processing chamber.

In one aspect, the laser beam is configured to cross a direction of the flow stream of the particles in the exhaust line at an angle. In one aspect, the imaging detector is configured to view the laser beam at a substantially perpendicular angle. In one aspect, the imaging detector is mounted on a detector housing that provides a view to the imaging detector that is orthogonal with respect to the laser beam or laser sheet. For example, the detector housing may be polygon with four or more sides, such as an octagonal detector housing or a cube-shaped detector housing, such that the imaging detector is mounted perpendicular to a viewport of the detector housing.

In one aspect, the particle detection system includes a second laser beam that is directed into an air space or vapor space of the housing of the process device and an imaging detector that is mounted with a perpendicular view of the second laser beam in the housing of the process device. In one aspect, the system further includes a purge system configured to direct particles out of the process device and into the exhaust line. In one aspect, the system further includes a vacuum system configured to draw particles out of the process device and into the exhaust line.

In one aspect, the system further includes a throttle valve that is configured to impede at least a portion of the flow stream. In one aspect, the throttle valve is configured to direct the particles to flow through an aperture that is smaller than a cross-sectional area of the exhaust line. In one aspect, the throttle valve has a coupon configured to collect a portion of the particles. In one aspect, the laser beam is directed to a surface of the coupon. In one aspect, the laser beam is directed by a galvanometer mirror. In one aspect, the laser beam is directed by mirrors to cross the flow stream in multiple locations. In one aspect, the multiple stream crossings form an array of laser beams.

In one aspect the technology includes a method to mount a second laser beam that is directed into an air space of the housing of the process device, mount an imaging detector with a perpendicular view of the second laser beam in the housing of the process device, and detecting particles in the process device as the particles pass through the laser beam. In one aspect, the method includes mounting a second laser beam that is directed into an air space of the housing of the process device, mounting an imaging detector with a perpendicular view of the second laser beam in the housing of the process device, and detecting particles in the process device as the particles pass through the laser beam. In one aspect, the method includes engaging a purge system to direct particles from the process device out through the exhaust line.

Other technical features may be readily apparent to one skilled in the art from the following figures, descriptions, and claims.

### BRIEF DESCRIPTION OF THE SEVERAL VIEWS OF THE DRAWINGS

The presently disclosed subject matter can be better understood by referring to the following example figures. The components in the figure are not necessarily to scale, emphasis instead being placed upon illustrating the principles of the presently disclosed subject matter (often schematically). In the figures, like reference numerals designate corresponding parts throughout the different views. A further understanding of the presently disclosed subject matter can be obtained by reference to an embodiment set forth in the illustrations of the accompanying drawing. Although the illustrated embodiment is merely for purposes of example of systems for carrying out the presently disclosed subject matter, both the organization and method of operation of the presently disclosed subject matter, in general, together with further objectives and advantages thereof, may be more easily understood by reference to the drawings and the following description. The drawings are not intended to limit the scope of this presently disclosed subject matter, which is set forth with particularity in the claims as appended or as subsequently amended, but merely to clarify and provide examples of the presently disclosed subject matter.

FIG. 1 illustrates a particle detection system in a process chamber and in an exhaust line in accordance with one embodiment.

FIG. 2 illustrates a particle detection system in an exhaust line in accordance with one embodiment.

FIG. 3 illustrates a cube mount housing for a particle detection system in an exhaust line in accordance with one embodiment.

FIG. 4 illustrates an octagon mount housing for a particle detection system in an exhaust line in accordance with one embodiment.

FIG. 5 illustrates a flow restrictor for a particle detection system in an exhaust line in accordance with one embodiment.

FIG. 6 illustrates a throttle valve for a particle detection system in an exhaust line in accordance with one embodiment.

FIG. 7 illustrates a throttle valve collection zone for a particle detection system in an exhaust line in accordance with one embodiment.

FIG. 8 is a block flow diagram of a method to use a particle detection system in a process chamber and in an exhaust line in accordance with one embodiment.

FIG. 9 illustrates a schematic of an example apparatus/system according to implementations of the disclosure.

### DETAILED DESCRIPTION

Processes in accordance with the present disclosure will now be described more fully hereinafter with reference to the accompanying drawings, where various embodiments are shown. The processes may be embodied in many different forms and are not to be construed as being limited to the embodiments set forth herein. Instead, these embodiments are provided so the disclosure will be thorough and complete, and will fully convey the scope of the methods to those skilled in the art.

The terminology used herein is for the purpose of describing particular embodiments only and is not intended to be limiting of the presently disclosed subject matter. While the following terms are believed to be well understood by one of ordinary skill in the art, the following definitions are set forth to facilitate explanation of the presently disclosed subject matter.

All technical and scientific terms used herein, unless otherwise defined below, are intended to have the same meaning as commonly understood by one of ordinary skill in the art. References to techniques employed herein are intended to refer to the techniques as commonly understood in the art, including variations on those techniques or substitutions of equivalent techniques that would be apparent to one of skill in the art. While the following terms are believed to be well understood by one of ordinary skill in the art, the following definitions are set forth to facilitate explanation of the presently disclosed subject matter.

In describing the presently disclosed subject matter, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

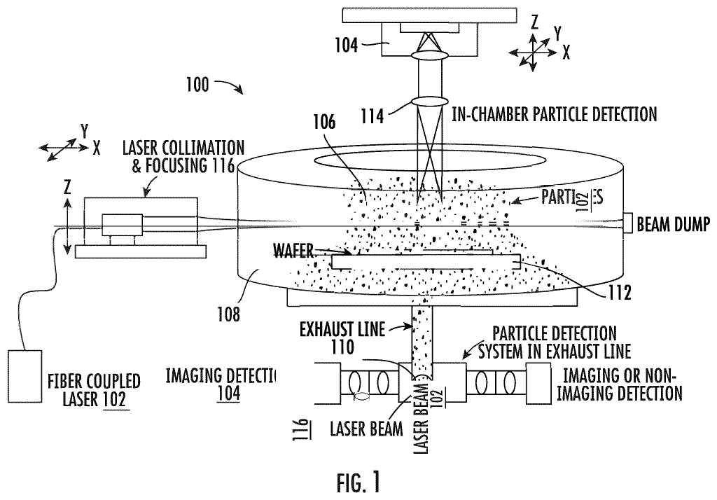

FIG. 1 illustrates a particle detection system 100 in a process chamber 108 and in an exhaust line 110 in accordance with one embodiment.

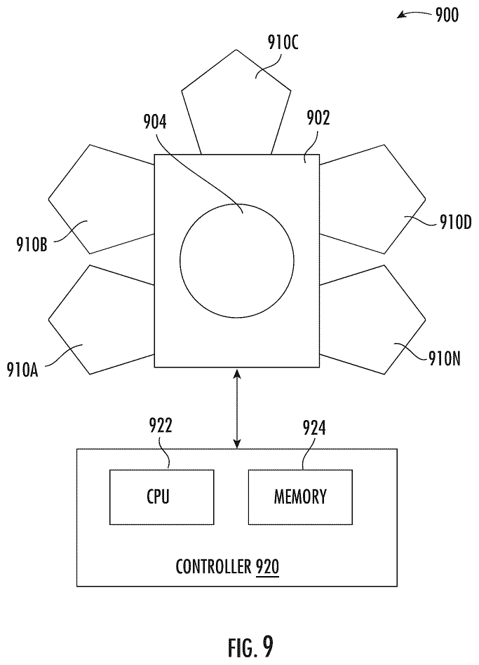

In the illustration, a process chamber 108 is used to process a wafer 112. An example chamber 108 configuration is described in greater detail with respect to FIG. 9 below. The wafer 112 may be processed in the construction of an integrated circuit device. Particles 106 may be present in the chamber 108 either suspended in the gas over and around a wafer 112, deposited on a wall or other surface in the chamber 108, or even on the wafer 112. The particles 106 may be described herein as particulates, contaminants, or other suitable terms. The particles 106 may be solid particles, such as a rubber particulate, or a liquid, such as a droplet of condensation.

In an example, a purge system may be used to remove the particles 106 from the chamber 108 through an exhaust line 110. The purge system may include a pressurized inlet of air or gas that is piped into the body of the chamber 108. The pressurized gas forces air, including the particles 106, out of a port to an exhaust line 110 for removal from the chamber 108. In an example, an inlet for the purge gas is opposite the exhaust port to cause a flow of air and gas through the body of the chamber 108 to remove particles 106 from the air. The flow of air may further scrub the particles 106 from surfaces in the chamber 108, suspend the particles 106 in the flowing air, and transport the particles 106 out of the chamber 108.

The particle detection system 100 may be used as a non-contacting sensor to determine a number of particles 106 in the chamber 108 and/or a number of particles 106 passing out of the exhaust line 110. The particle detection system 100 may include a non-contacting laser beam 102 that is generated by a fiber coupled laser head and directed to a beam shaping system 116. The beam shaping system 116 uses beam shaping optics or other techniques or processes to adjust the laser beam 102 to achieve a desired path, spread, and focus. For example, the beam shaping optics may cause the laser beam 102 to be configured as a laser sheet. The laser sheet may be a flat planar laser beam that covers a section of the chamber 108 or exhaust line 110 such as a horizontal plane or an angled plane. In examples herein, a laser beam 102 may be described as a laser sheet or a focused laser spot. Further, when described as a laser beam 102, the laser beam 102 may be a laser sheet or a focused laser spot, based on the application and configuration of the laser beam 102. The laser beam 102 may pass through the environment and be received by a laser dump that prevents reflection, refraction, or scattering of the laser beam. In another example, the laser beam 102 or the laser sheet may be a collimated beam. That is, the laser shaping optics may form the beam into a column to increase the sensitivity for a smaller footprint of coverage.

As illustrated, the laser beam 102 may be directed inside the chamber 108 to detect particles 106 in an air space of the chamber 108. The laser beam 102 is also illustrated as being directed through the exhaust line 110 to capture particles 106 flowing out of the chamber 108.

In another example, the laser beam 102 may include multiple laser beams 102 that are directed to cover a single area simultaneously. The multiple laser beams 102 may serve to provide a more distinct light scattering when crossed by a particle 106. In another example, a single laser beam 102 may be split into multiple laser beams 102 covering multiple locations.

In another example, a single laser beam 102 may be multiplied by one or more mirrors or other reflective surfaces. The laser beam 102 may be reflected back into a zone containing particles 106 to cover additional areas in conjunction with the first laser beam 102. For example, the laser beam 102 may be reflected multiple times, such as 2, 3, 5, 7, or 10 times to create a laser array that covers a three-dimensional volume of the chamber 108 or the exhaust line 110. The laser beams 102 may be stacked vertically to cover a volume of arrayed layers.

The particle detection system 100 includes an imaging detector 104. The imaging detector 104 may be a camera or other optical device that captures laser light scattered by particles 106 that cross or enter the laser beam 102. A processing unit of the particle detection system 100, such as a computing device, may receive the image from the imaging detector 104 and identify the scattered light images.

The processing unit may interpret the images to identify a number and/or speed of the particles 106. The processing unit may identify the number of the particles 106 in an instantaneous image or calculate a number of particles 106 that are imaged over a period of time, such as with a series of images or a video. The image may include light that is scattered when the particle 106 passes through the laser beam 102 and scatters the laser light towards the image detector 104. The image detector 104 captures the scattered light in an image, a video, or other suitable format.

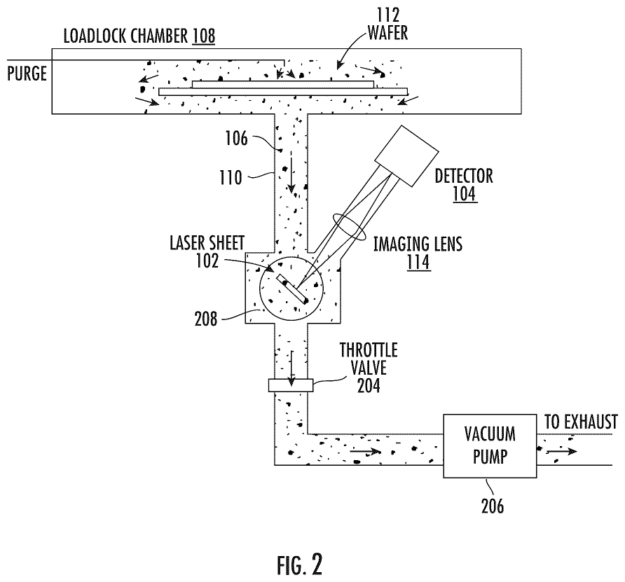

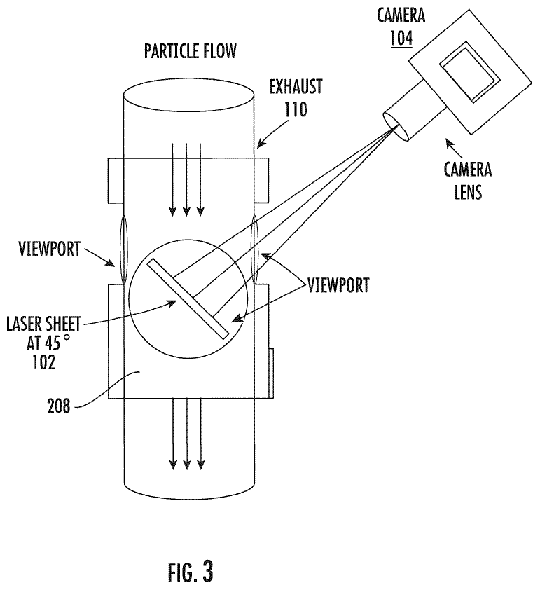

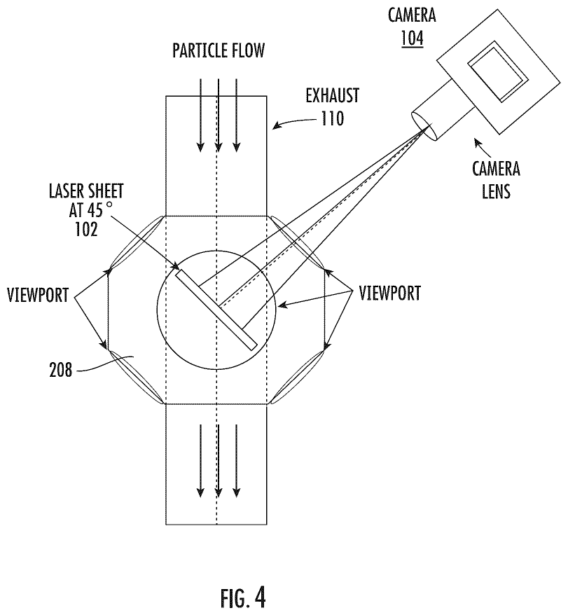

The system may detect and measure particles that are moving at a high speed, such as greater than 10 m/s, 20 m/s, 30 m/s, or 40 m/s. Conventional systems do not have a field of view that is as large as described herein with same signal collection efficiency. Other conventional systems do not have a laser sheet or other laser source that provides a sufficient laser beam 102 to capture the particle 106. Conventional systems are arranged in a manner that the image detector does not have a direct view of the laser scattered beam. Conversely, the imaging detector 104 may be arranged as described below with respect to FIG. 2, FIG. 3, FIG. 4 and other embodiments herein to capture an undistorted, full field of view with better signal collection efficiency than conventional systems. The particle detection system 100 may further determine a speed of a particle 106 that is captured by the imaging detector 104. The imaging detector 104 may capture a particle as a streak that is created because the particles 106 is moving during the time that the image is captured. By determining the length of the streak and the time that the image captured, a speed of the particles 106 may be determined.

In an example, the particle detection system 100 may capture particles that are too small for conventional systems, such as 50 nm, 60 nm, 70 nm, 80 nm, 90 nm, 100 nm, 120 nm, 150 nm, or 200 nm. The particle detection system 100 is able to capture smaller particles 106 and/or particles 106 moving at faster speeds because of the laser beam configuration, the angled mounting of the laser beam 102 and the imaging detector 104, the process flow conditioning elements, and other features described herein.

The particle detection system 100 may use the detected particles 106 to determine a health and status of the processing system. For example, a higher number of particles 106 may indicate that the chamber 108 requires cleaning or a process element of the chamber requires replacement. In an example, a process seal ring may be degrading, which releases particles 106 in the air. In another example, excessive condensation particles 106 are building up in the chamber 108. By identifying and categorizing the particles 106, the particle detection system 100 is able to provide a feedback loop to allow optimization of chamber 108 operations.

FIG. 2 illustrates a particle detection system in an exhaust line in accordance with one embodiment.

The particle detection system 100 of FIG. 2 employs similar devices as described with respect to FIG. 1. The chamber 108 has a wafer 112 that is being processed. The chamber 108 includes particles 106 that are being directed to an exhaust line 110 by a purging system. The exhaust line 110 has a detector housing 208 in the flow of the particles 106. In the example, the purging system is performed or aided by a vacuum pump 206 in the exhaust line 110. The vacuum pump 206 creates a negative pressure on the chamber 108 to draw air, gas, vapors, and particles 106 from the chamber 108.

The detector housing 208 may be connected to the exhaust line 110, such as with a flanged connection, a screwed connection, or in any other suitable manner. The detector housing 208 may have a connection to allow a laser beam 102 to be directed into the detector housing 208 and through the flow path of the particles 106. The detector housing 208 may include an imaging detector 104 that is mounted to the detector housing 208, such as with a flanged connection, a screwed connection, or in any other suitable manner. The imaging detector 104 may include an imaging lens 114 to focus the image and improve the resolution and clarity of the images.

In an example, the laser beam 102 is a laser sheet that covers all or a portion of the flow path of the particles 106. The laser beam 102 is further illustrated as being configured at an angle through the flow path. For example, the laser beam 102 is configured to be at an angle compared to the vertical flow path. The angle may be any suitable angle for capturing most or all of the particles while allowing unobstructed sight lines to the image detector 104. For example, the angle may be 30 to 60 degrees, 40 to 50 degrees or optimally 45 degrees.

The imaging detector 104 of the example is directed at an opposing angle to the vertical such that the view of the imaging detector 104 is perpendicular to the laser beam 102. For example, the angle may be and opposing 30 to 60 degrees, 40 to 50 degrees or optimally 45 degrees. In this manner, the imaging detector 104 obtains a full unobstructed view of the plane of the laser beam 102 without interrupting the flow of the exhaust line 110. The perpendicular view of the laser beam 102 allows for a non-distorted image as opposed to an image captured of the laser beam 102 at a sharper angle.

A throttle valve 204 is illustrated after the detector housing 208. The throttle valve 204 may be used to slow or stop the flow of the particles in the exhaust line 110. For example, the throttle valve may slow the flow to allow the particles to have more time in the detector housing 208. In another example, the throttle valve 204 may slow the particles 106 to prevent a particle 106 from passing through the field of view at a speed that prevents detection.

FIG. 3 illustrates a cube mount housing 208 for a particle detection system 100 in an exhaust line 110 in accordance with one embodiment.

The illustration depicts one configuration of a detector housing 208 as described in FIG. 2. The mounting of the detector housing 208 is in a cube fashion such that the imaging detector 104 is perpendicular to the laser beam 102. The view of the imaging detector 104 is through a viewport in the body of the detector housing 208 at an angle. The laser beam 102 is directed at a suitable angle across the housing flow path. For example, the laser beam 102 is a laser sheet that covers at least a portion of the cross-sectional area of the flow path at a 45-degree angle with respect to the flow path or other suitable angle. The view of the imaging detector 104 is at an angle that allows a full view of the laser sheet. For example, the angle of view for the imaging detector 104 is perpendicular to the laser sheet. For example, the angle of view for the imaging detector 104 may be at an angle of 85, 90, or 95 degrees with respect to the laser sheet and/or at an angle of 40, 45, or 50 degrees with respect to the flow path. Any suitable angles for the laser sheet and the imaging detector that provides a full field of view may be envisioned. The view ports and configuration of the detector housing 208 may be configured to alter the angles of the laser beam 102 and the angle of the imaging detector view to allow different depth and positions of the exhaust line to be probed. In one example, the view ports may be configured at an angle that is perpendicular to the view angle of the imaging detector 104. In another example, the view ports may be configured at an angle that is intentionally not perpendicular to the view of the laser beam 102 to minimize scattering or reflective light being seen in the view. The view ports may be configured such that the laser beam 102 passes through the view port at Brewster's angle. Brewster's angle, also called the polarization angle, is the angle of incidence at which light with a particular polarization is perfectly transmitted through a transparent surface without any reflection. The angle is configured such that the refracted and reflected light rays are perpendicular to each other. In an example, the view ports may be 2, 5, 10, 15, or 20 degrees from perpendicular to minimize the light scattering.

The detector housing 208 may be mounted to the exhaust line 110 via a flanged connection, a screwed connection, or in any other suitable manner. The particles 106 flow through the detector housing 208 and cross the sheet of laser light provided by the laser beam 102. When the particles 106 cross the laser beam 102 and scatter the light, the imaging device 104 captures the scattered light. As can be appreciated in the illustration, the imaging device 104 is not disturbing the flow of particles 106 but still maintains a face-on, perpendicular view of the sheet created by the laser beam 102.

In an example, the detector housing 208 and other components, such as the view ports and the laser dump, are constructed of low scatter components. Low scatter components reduce the amount of background light scatter, improves the system's precision, and reduces false identifications. The view ports may be constructed of a transparent, high optical purity material to minimize scattering and maximize transmission of laser light The view ports may be constructed of low scattering and/or nonreflective materials. The low scattering glass of the view ports prevents reflections and scattered light from being viewed by the imaging device 104 and interpreted falsely as additional particles 106. The view ports may be manufactured of a transparent material such as glass, quartz, sapphire, silicon carbide, or any other suitable material. The view port may receive one or more coatings, surface treatments, or other additives or treatments that cause the view port to be non-reflective and non-scattering of light.

FIG. 4 illustrates an octagonal mount housing 208 for a particle detection system 100 in an exhaust line in accordance with one embodiment.

The illustration depicts a detector housing 208 in an exhaust line 110, as described in FIG. 2. The mounting of the detector housing 208 is in an octagonal fashion such that the imaging detector 104 is perpendicular to the laser beam 102. In other examples, the detector housing 208 is any polygon shaped housing with four or more sides, such as with 6, 8, or 10 sides. As opposed to the cube mount of FIG. 3, the viewport is configured to be parallel to the laser beam 102 and perpendicular to the imaging detector 104. In this manner, the imaging detector 104 has a view through the viewport and to the flat plane of the laser beam 102 such that the image is not distorted. In other examples, the laser beam 102 is configured at a different angle that covers at least a portion of the cross-sectional area of the detector housing 208. The angle of the imaging detector 104 may be altered to remain perpendicular to the plane of a laser sheet.

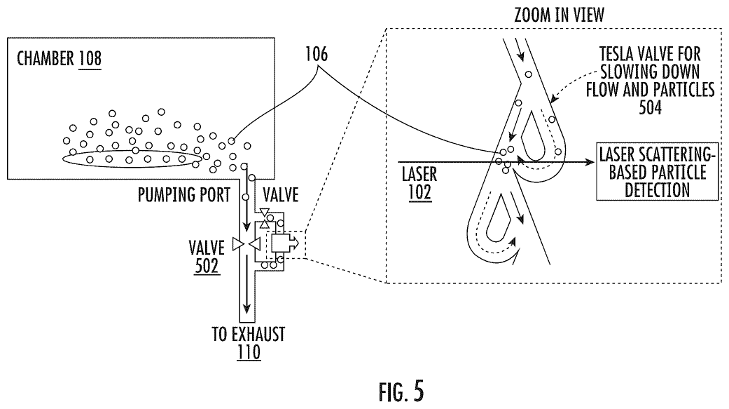

FIG. 5 illustrates a flow restrictor 504 for a particle detection system 100 in an exhaust line 110 in accordance with one embodiment.

In the image, a chamber 108 is depicted with particles 106 entrained in the air. The particles 106 are directed down the exhaust line 110. In the example, a valve 502 is in the primary exhaust line 110 to stop or slow the flow as required. A bypass line directs the flow to a detector housing 208 that includes a flow restrictor 504.

The flow enters the detector housing 208 and is directed through a flow restrictor 504 device, such as a Tesla valve, that slows the flow by creating a tortuous path via obstructions or other mechanical restrictions. The laser beam 102 is directed through a slowed portion of the flow restrictor 504. The slowed particles 106 pass more slowly through the laser beam 102. An imaging detector 104 captures images of the light scattered by the particles 106. Any other suitable type of flow restrictor 504 may be used to create one or more pockets of slowed exhaust flow. The slowed particles 106 are easier to detect by the imaging detector 104.

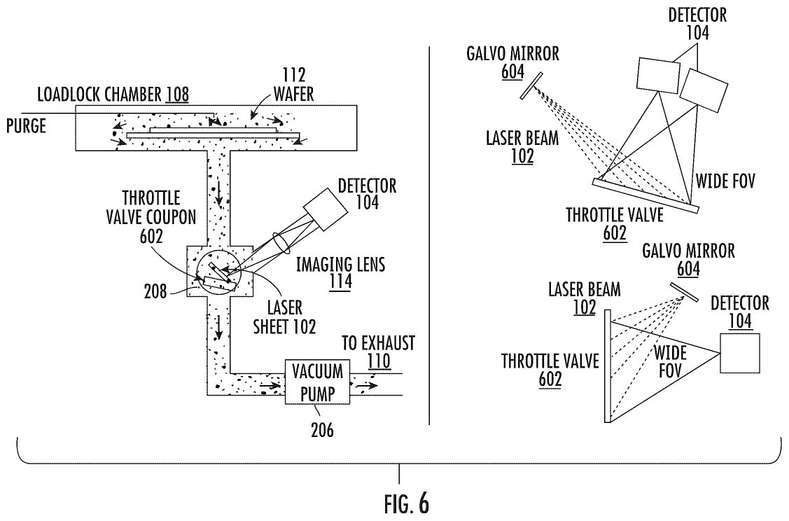

FIG. 6 illustrates a throttle valve 204 with a coupon 602 for a particle detection system 100 in an exhaust line in accordance with one embodiment.

A particle detection system 100 is illustrated that operates in a similar manner as FIG. 2 but with a throttle valve coupon 602 in the detector housing 208. For example, a chamber 108 has a wafer 112 that is being processed. Particles 106 in the chamber 108 may be suspended in the air. In other examples, a purge system may pump air, nitrogen gas, or any other fluid into the chamber 108 to dislodge any particles from the walls, processing equipment, the wafer, or any other surface. The particles 106 may be dislodged and suspended in the air space of the chamber 108. After the purge or any other suitable time, the particles 106 may be directed to an exhaust line 110 by a vacuum pump 206 in the exhaust line 110 or any other suitable motive force. The exhaust line 110 has a detector housing 208 in the flow of the particles 106.

The detector housing 208 may be connected to the exhaust line 110, such as with a flanged connection, a screwed connection, or in any other suitable manner. The detector housing 208 may have a connection to allow a laser beam 102 to be directed into the detector housing 208 and through the flow path of the particles 106. The detector housing 208 may include an imaging detector 104 that is mounted to the detector housing 208, such as with a flanged connection, a screwed connection, or in any other suitable manner. The imaging detector 104 may include an imaging lens 114 to focus the image and improve the resolution and clarity of the images.

In the illustration, a seat or surface of the throttle valve 204 may have a flat, planar surface that acts as a throttle valve coupon 602. The throttle valve coupon 602 may lie across the full path or at least a portion of the path of the particles 106 entering the detector housing 208. Particles 106 may strike the surface of the throttle valve coupon 602 or settle onto the surface of the throttle valve coupon 602.

A laser beam 102 may be distributed across the surface of the throttle valve coupon 602. In an example, a galvo mirror 604 directs a laser beam 102 across the surface as illustrated in the two examples of FIG. 6. A galvo mirror 604, or galvanometer mirror, may be a device to control the direction and spread of a laser beam 102 by rapidly moving mirrors to direct the laser beam 102. For example, the galvo mirror 604 may direct the laser beam 102 to scan across a surface of the throttle valve coupon 602 to illuminate particles across all or a section of the throttle valve coupon 602. One or more imaging detectors 104 may be mounted at an angle to achieve a full view of the surface of the throttle valve coupon 602, such as at a perpendicular angle to the throttle valve coupon 602. In another example, a commercial particle counter may be used to count the particles on the throttle valve coupon 602 or another coupon to validate the particle counts of the particle detection system 100. For example, a throttle valve coupon 602 may be removed from the detector housing 208 or otherwise accessed to verify the particle count.

In one example, the throttle valve 204 closes for a configured period of time to allow particles 106 to settle onto the throttle valve coupon 602. The imaging detector 104 records a number of particles 106 on the surface. The throttle valve 204 may subsequently open and allow the particles to be swept off the throttle valve coupon 602 and to continue out through the exhaust line 110. The throttle valve 204 may then be closed again to allow a subsequent batch of particles 106 to settle on the coupon 602. In another example, the particles 106 do not necessarily settle on the throttle valve coupon 602 but are stopped or slowed in the detector housing 208 to allow for detection by the imaging detector 104 either on the surface or suspended above the surface.

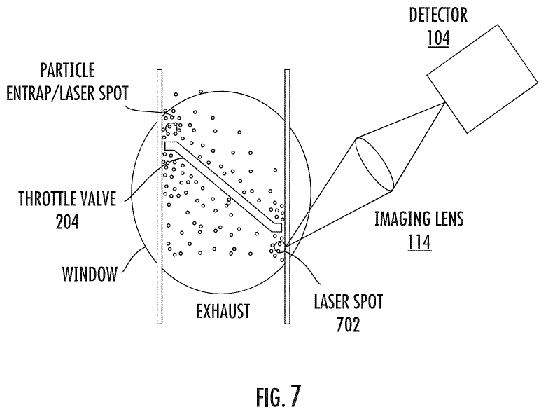

FIG. 7 illustrates a throttle valve collection zone for a particle detection system 100 in an exhaust line in accordance with one embodiment.

In FIG. 7, a system as described in FIG. 2 may be employed with a throttle valve 204 causing particles to be collected in one or more collection zones 702. A throttle valve 204 may be used as described herein. The throttle valve 204 interrupts the flow of the particles 106 in the exhaust line 110. The flow is forced to proceed through an opening that is smaller than the cross-sectional area of the exhaust line 110. For example, the throttle valve 204 is partially opened to force the flow through a small aperture around the surface of the throttle valve 204.

Because the particles are forced, or herded, through the smaller aperture, the particles are collected and packed into a smaller volume. In an example, the laser beam 102 is not spread across the entire area of the exhaust line 110 but is instead focused on the aperture through which the particles 106 are forced. Because some or all of the particles 106 are passing through the smaller space, the laser beam 102 may be more tightly focused. The particles 106 may cause a more distinct scattering due to the more focused laser beam 102.

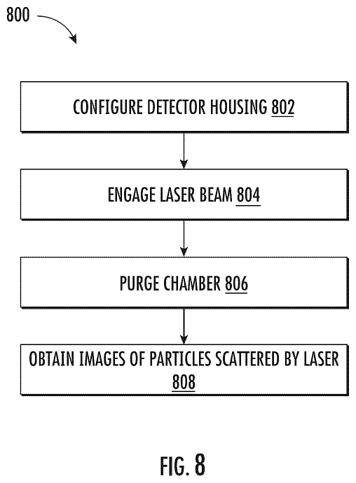

FIG. 8 is a block flow diagram of a method to use a particle detection system in a process chamber and in an exhaust line in accordance with one embodiment.

In block 802, the method 800 configures a detector housing 208. For example, an operator or other user may select a detector housing 208 such as a cube housing as described in FIG. 3 or an octagonal housing as described in FIG. 4. The detector housing 208 may have some or all of the components as described herein, such as a laser beam 102 and an imaging detector 104. An imaging detector 104 may be similarly configured to mount on the chamber 108.

In block 804, the method 800 engages a laser beam 102. For example, a laser sheet may be formed from the laser beam 102 to cover at least a portion of the cross-sectional area of the detector housing 208 or the exhaust line 110. The laser beam 102 may use a laser collimation and focusing system 116, a galvo mirror 604, or any other suitable devices or systems to control and direct the laser beam 102.

In block 806, the method 800 purges the chamber 108. The method 800 may engage a pump or blower to force air, nitrogen gas, or any other fluid into the chamber 108 to dislodge particles from the walls, processing equipment, the wafer, or any other surface. The particles 106 may be dislodged and suspended in the air space of the chamber 108. After the purge or any other suitable time, a vacuum pump 206 may be engaged to provide a force to draw the particles 106 out of the exhaust line 110. The throttle valve 204 may be opened to allow flow through the exhaust line 110.

In block 808, the method 800 obtains images of particles scattered by the laser beam 102. The particles 106 may scatter the laser beam 102 light as described herein and be detected by the imaging detector 104. The images may be collected, processed, sorted, and analyzed by a user, a computing system, or other system or device to identify particles 106 in the image. The method 800 may identify a number, size, speed, and shape of the particles 106. The method 800 may use the data to determine if the chamber 108 needs to be cleaned, replaced, repaired, or purged further.

FIG. 9 shows a schematic of an example apparatus/system 900 according to implementations of the disclosure. In some implementations, the system 900 may be a cluster tool operable to perform processes necessary to form integrated circuit devices, such as on a wafer. Examples of processing systems that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

As shown, the system 900 may include at least one central transfer station/chamber 902 and one or more robots 904 within the transfer station/chamber 902, wherein the robot 904 is operable to move a robot blade and a wafer to and from each of a plurality of processing chambers 910A-910N connected with, or positioned adjacent to, the transfer station/chamber 902. In some implementations, the processing chambers 910A-910N may support ion implantation, material deposition, material etching, thermal processing, and others. The particular arrangement of process chambers and components can be varied depending on the cluster tool and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some implementations, processing chamber 910A may be a deposition chamber operable to deposit one or more layers or features of the stack of layers on a wafer. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition. The deposition chamber may further be an epitaxial growth deposition chamber or any suitable deposition chamber, such as SACVD, LPCVD, or ALD.

In some implementations, processing chamber 910B may be an etch chamber operable to form one or more trenches. In some implementations, processing chamber 910B may be used for wet and/or dry etch processes.

In some implementations, processing chamber 910C may be operable to perform a nitridation process a wafer, while processing chamber 910D may be operable to perform one or more thermal processes, such as an annealing or a rapid thermal processing.

In the examples herein, one or more of the chambers 910A-910N are purged to remove airborne particulates or particulates that have deposited on a wall or other surface of the chambers 910A-910N. As described in the processes herein, the particulates are exhausted out of the chambers 910A-910N. The technologies described herein measure the particulates.

A system controller 920 is in communication with the robot 904, the transfer station/chamber 902, and the plurality of processing chambers 910A-910N. The system controller 920 can be any suitable component that can control the processing chambers 910A 910N and robot(s) 904, as well as the processes occurring within the process chambers 910A 910N. For example, the system controller 920 can be a computer including a central processor 922, memory 924, suitable circuits/logic/instructions, and storage.

Processes or instructions may generally be stored in the memory 924 of the system controller 920 as a software routine that, when executed by the processor 922, causes the processing chambers 910A-910N to perform processes of the present disclosure. The software routine may also be stored and/or executed by a second processor (not shown) that is remotely located from the hardware being controlled by the processor 922. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 922, transforms the general-purpose computer into a specific purpose computer (controller) that controls the chamber operation such that the processes are performed.

For the sake of convenience and clarity, terms such as “top,” “bottom,” “upper,” “lower,” “vertical,” ‘horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one implementation” of the present disclosure are not intended as limiting. Additional implementations may also incorporate the recited features.

Furthermore, the terms “substantial” or “substantially,” as well as the terms “approximate” or “approximately,” can be used interchangeably in some implementations, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific implementations described herein. Indeed, other various implementations of and modifications to the present disclosure, in addition to those described herein, will be apparent to those of ordinary skill in the art from the foregoing description and accompanying drawings. Thus, such other implementations and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

While the present invention has been described in terms of one or more preferred embodiments, it is to be understood that other modifications may be made without departing from the scope of the invention, which is set forth in the claims below.

That which is claimed is:

1. A particle detection system, comprising:
a detector housing mounted on a flow stream associated with a process device;
a laser beam that is directed into a flow stream of particles in the flow stream; and
an imaging detector that is mounted with a perpendicular view of the laser beam.

2. The particle detection system of claim 1, wherein the laser beam is positioned in an exhaust line of the process device and is configured as a laser sheet that covers at least a portion of a cross-sectional area of the exhaust line.

3. The particle detection system of claim 2, wherein the laser sheet is formed by beam shaping optics.

4. The particle detection system of claim 2, wherein the laser sheet is configured to cross a direction of the flow stream of the particles in the exhaust line at an angle.

5. The particle detection system of claim 1, wherein the process device is a wafer processing chamber.

6. The particle detection system of claim 4, wherein the imaging detector is configured to view the laser sheet at a substantially perpendicular angle.

7. The particle detection system of claim 6, wherein the imaging detector is mounted on a detector housing that is a polygon-shaped housing with four or more sides such that the imaging detector is mounted perpendicular to a view port of the detector housing.

8. The particle detection system of claim 1, wherein a view port through which the laser beam enters the flow stream is configured at an angle to optimize transmission and minimize back reflection of polarized light passing through said windows.

9. The particle detection system of claim 8, wherein the view port is constructed of a transparent, high optical purity material to minimize scattering and maximize transmission of the laser beam.

10. The particle detection system of claim 1, wherein the laser beam is positioned in an air space of the process device and is configured as a laser sheet that covers at least a portion of a cross-sectional area of the process device.

11. The particle detection system of claim 1, wherein the laser beam is positioned in an exhaust line of the process device and the particle detection system further comprises:
a second laser beam is directed into an air space of the housing of the process device; and
a second imaging detector that is mounted with a perpendicular view of the second laser beam in the housing of the process device.

12. The particle detection system of claim 2, further comprising a vacuum pump configured to draw particles out of the process device and into the exhaust line.

13. The particle detection system of claim 2, further comprising a vacuum system configured to draw particles out of the process device and into the exhaust line.

14. The particle detection system of claim 2, further comprising a throttle valve that is configured to impede at least a portion of the flow stream and direct the particles to flow through an aperture that is smaller than a cross-sectional area of the exhaust line.

15. The particle detection system of claim 14, wherein the throttle valve comprises a coupon configured to collect a portion of the particles.

16. The particle detection system of claim 15, wherein the laser sheet is directed to a surface of the coupon by a galvanometer mirror.

17. The particle detection system of claim 1, wherein the laser beam is directed by mirrors to cross the flow stream in multiple locations to form an array of laser beams.

18. The particle detection system of claim 1, wherein the laser beam is configured as a column.

19. A method to detect airborne particles, comprising:
mounting a detector housing on an flow stream of a process device;
directing a laser beam into a flow stream of particles in the flow stream;
mounting an imaging detector with a perpendicular view of the laser beam; and
detecting particles in the flow stream as the particles pass through the laser beam.

20. The method of claim 19, further comprising:
wherein the first flow stream is in an exhaust line of the process device, and the method further comprises:
mounting a second laser beam that is directed into an air space of the housing of the process device;
mounting a second imaging detector with a perpendicular view of the second laser beam in the housing of the process device; and
detecting particles in the process device as the particles pass through the laser beam.

21. The method of claim 19, further comprising engaging a vacuum pump to draw particles from the process device out through the exhaust line.
